(19) United States
(12) Patent Application Publication
(10) Pub. No.: US 2006/0208928 A1
(43) Pub. Date: Sep. 21, 2006

(54) Encoding scheme to resist code injection attacks

(76) Inventors: Paul Mackerras, Weston (AU); Paul F. Russell, Queanbeyan (AU)

Correspondence Address: LIEBERMAN & BRANDSDORFER, LLC, 802 STILL CREEK LANE, GAITHERSBURG, MD, 20878, US

(21) Appl. No.: 11/011,992

(22) Filed: Dec. 14, 2004

(51) Int. Cl. H03M 7/00

(52) U.S. Cl. 341/50

(57) ABSTRACT

A method and system are provided for encoding program instructions, and for decoding the encoded program instructions prior to execution. An encoded set of program instructions is provided by combining a single page of decode instructions with a set of unencoded program instructions. The page of decode instructions is set at an address which may be located by means of a hardware register. Prior to execution of the encoded set of program instructions, the location of the decode page is ascertained by consulting the assigned hardware register. The decode page is combined with the encoded program instructions to produce a stream of executable program instructions.

### BACKGROUND OF THE INVENTION

1. Technical Field

This invention relates to a method and system for encoding a set of program instructions. More specifically, program instructions are encoded with a portable element for decoding the associated instructions upon execution.

2. Description of the Prior Art

A computer contains memory that stores an executable program with a set of associated program instructions. The program instructions are encoded into memory as numbers, also known as machine code. At the time of execution, the program instructions are decoded and executed to perform an operation. An error or defect in software or hardware that causes a program to malfunction is known as a bug. Often a bug is caused by conflicts in software when applications try to run in tandem. Similar to a bug, a program or piece of code may be loaded onto your computer without your knowledge and runs against your wishes. Such a program or code is called a virus. All computer viruses are man made. Some viruses can be self replicating. If a bug or virus is provided with an opportunity to overwrite the program instructions, i.e. the machine code, or to replace the program instructions in memory, and the program instructions are executed, the computer program will not function properly as it will be executing improper instructions.

Encoding of instructions into machine code is usually part of the design of a particular processor. For example, many Intel processors use i386 machine code, and Apple processors use PowerPC machine code. However, if the encoding of machine code is not known prior to the actual execution, it becomes difficult to insert a bug or virus into the program instructions to achieve a desired result. For example, machine code 2200 might be an instruction to load data from memory in a first computer and machine code 2200 might be an instruction to load a key from the keyboard into a register on a second computer. A solution that encodes a program without prior knowledge of the hardware executing machine code would require software to translate instructions for specific processors to enable a program to work on different computers. Another shortcoming associated with embedding translation instructions for a specific processor is the complexity associated with this solution. Embedding software to translate instructions provides an additional step to the program execution which in effect slows the execution of the program instructions instead of enabling the program to execute faster, which is usually the desired result. Accordingly, there is a need for encoding program instructions to combat insertion of a bug or virus that does not affect speed of execution of processing instructions.

One solution that does not affect the speed of processing instructions is to combine the memory location of processing instructions of one location with its contents at a second location through a mathematical relationship. For example, a load from memory instruction at a first location and a load from keyboard instruction at a second location would utilize the same mathematical factor to translate an encoded instruction. A shortcoming for this approach is that some sets of instructions can be loaded into memory at different locations and would not function properly if changing the location changes the meaning of the instructions.

Therefore, there is a need for combating bugs and/or viruses in computer machine code in a manner that does not add complexity to the execution of the machine code. In addition, the solution needs to support relocation of programs to enable the program to properly function at more than one location.

### SUMMARY OF THE INVENTION

This invention comprises a method and system for encoding a program in a portable and efficient manner.

In a first aspect of the invention, a method is provided for encoding a program. A page is created to decode an encoded program instruction. Prior to program execution, the encoded program instruction is decoded with the page.

In another aspect of the invention, a computer system is provided with an encoded program instruction. A page is also provided for decoding the encoded program instruction. A manager applies the decode page to the encoded program instruction prior to execution of a program.

In yet another aspect of the invention, an article is provided with a computer-readable signal-bearing medium. Means in the medium are provided for creating a page to decode an encoded program instruction. In addition, means in the medium are provided for decoding the program instruction with the page prior to program execution.

Other features and advantages of this invention will become apparent from the following detailed description of the presently preferred embodiment of the invention, taken in conjunction with the accompanying drawings.

### BRIEF DESCRIPTION OF THE DRAWINGS

FIG. 1 is a flow chart illustrating a process for program creation according to the preferred embodiment of this invention.

FIG. 2 is a flow chart illustrating a process for program execution according to the preferred embodiment of this invention, and is suggested for printing on the first page of the issued patent.

FIG. 3a is a block diagram of binary data of a decode page.

FIG. 3b is a block diagram of a set of encoded program instructions.

FIG. 3c is a block diagram of a set of decoded program instructions.

### DESCRIPTION OF THE PREFERRED EMBODIMENT

### Overview

In resisting an injection attack of a bug or virus on a program, a page is created and stored in a memory location with instructions to decode a set of encoded program instructions. The decode page is set not to exceed the length of one page (typically 4096 bytes) as memory is divided into pages and relocatable programs are always moved by whole pages. Prior to executing the encoded program instructions, the decode page is applied to a corresponding page(s) of the program instructions to decode the associated instructions into a comprehensible stream of instructions. Upon execution of the decoded program instructions, a program is executed with coherent instructions. The decode page enables the program instructions to execute in an efficient manner and does not affect the overall efficiency of program operation.

### Technical Details

There are two primary components disclosed herein for resisting an injection attack on a program. The first component is related to creation of a computer program.

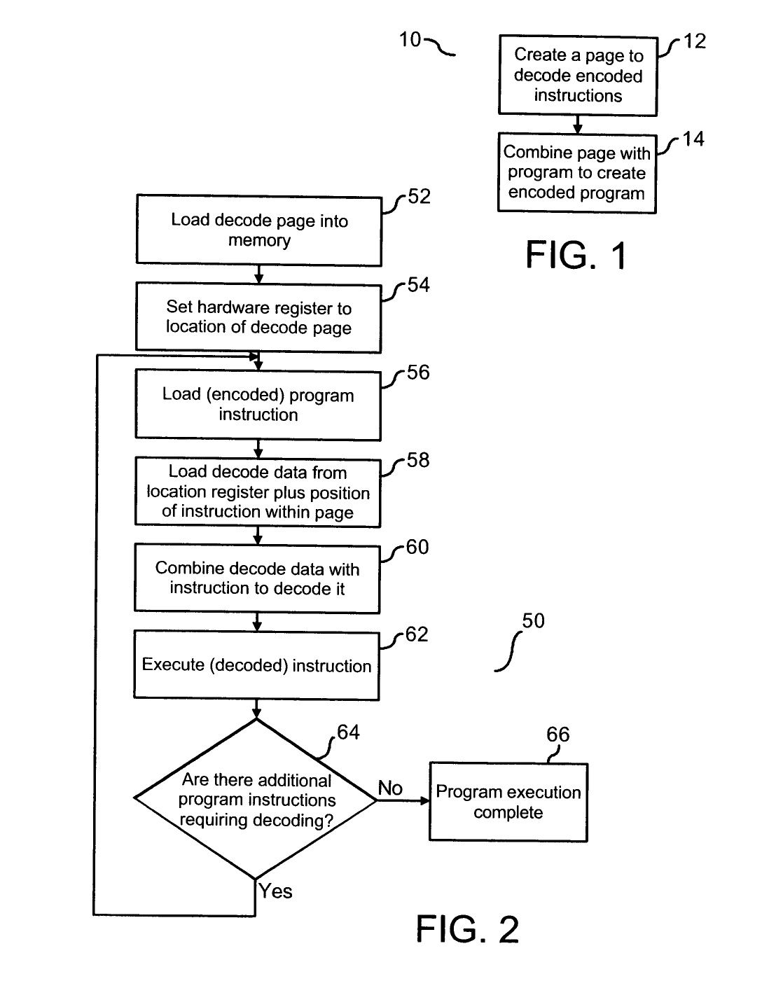

FIG. 1 is a flow chart (10) illustrating a process of creating a computer program designed to combat insertion of a bug and/or virus on embedded code. A set of decode instructions the size of a single page of memory is created at the same time as the program to decode associated instructions of a program that are encoded (12). The decode page (12) is specific to the program. Since memory is divided into pages, and relocatable programs are moved by whole pages, the decode page is provided in a size of one page of memory.

The page of decode instructions contains a pattern of data associated therewith that when combined with complementary instructions of a program will decode the program instructions and allow proper execution of the instructions. Following the creation of the decode page at step (12), the decode page is combined with a program to create an encoded program with associated encoded instructions (14). In one embodiment, instructions at each offset of the program may be combined with the contents of the page at the matching offset using a simple to implement binary operator, such as an exclusive OR operator, although other operators may be employed as well. Accordingly, the first part of the process for resisting an injection attack of a bug and/or virus is to encode the program with a pattern the size of a single page of memory embedded within a complementary set of instructions designed to decode the program.

Following the process of encoding the program instructions, the program instructions must be decoded with the page created in FIG. 1 prior to execution. FIG. 2 is a flow chart (50) illustrating a process for executing a set of encoded program instructions. Prior to program execution, the decode page created at step (12) is loaded into memory (52). The location of the decode page is preferably set in a hardware register of the associated computer housing the program instructions. In one embodiment, the hardware register identifying location of the decode page may change to a different hardware register for a subsequent execution of the same program instruction(s). Following step (52) and prior to execution of the program instruction, the hardware register is set to the location of the decode page (54). Upon loading a program instruction (56), the decode page is loaded from the location indicated in the hardware register in conjunction with the starting position of the instruction within the decode page.

Thereafter, the encoded program instruction is combined at an offset with contents of the associated decode page at a matching offset (60). In one embodiment, the process of combining the program instruction with the decode page may generate binary data to form a valid instruction stream. Following step (60), the decoded program instruction is executed (62), followed by a query to determine if there are additional encoded program instructions that require decoding with the associated decode page (64). A negative response to the query at step (64) is an indication that decoding of the program instructions for the associated page is complete (66). However, a positive response to the test at step (64) will return to step (56) for further decoding of program instructions. Accordingly, the operation of decoding program instructions is conducted on a page basis wherein a decode page is combined with each page of a set of program instructions prior to execution of the program instructions.

As shown in FIG. 1 and applied in FIG. 2, a decode page is created specific to a set of program instructions. The decode page is a single page. Although this page is referred to as a decode page, the same page may be referred to as an encode page since the same page is used to encode the set of program instructions. As described in FIGS. 1 and 2, the decode page in one embodiment is stored in a hardware register and implemented in a computer-readable medium as it is numerical data specific to program instructions in a machine readable format. In one embodiment, a page manager may be provided to determine the location of the decode page, and to redirect the location of the decode page to an alternative location for a subsequent execution of the program instructions, as well as another manager may be provided to direct the creation of the encode page and to apply the decode page to the program instructions at the specified position prior to program execution. The managers may be in the form of hardware elements within the computer system, or software elements in a computer-readable medium.

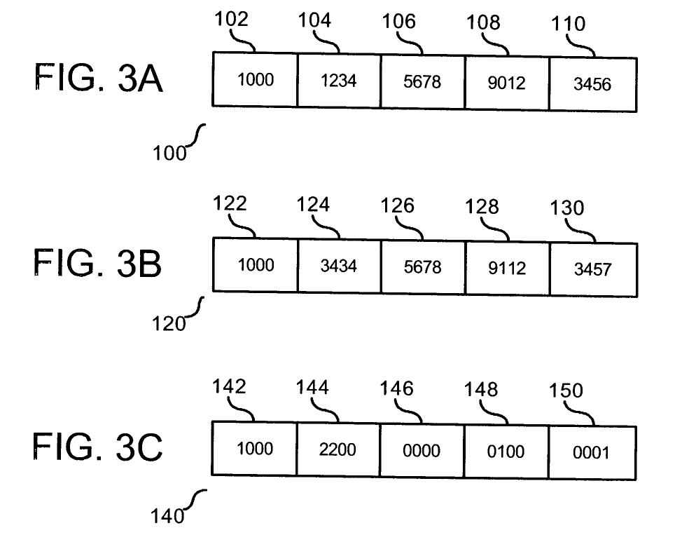

FIG. 3a is a block diagram (100) illustrating one example of numerical data associated with a decode page created in FIG. 1. As shown, at a set location (102), the decode page has numerical data (104), (106), (108), and (110). The decode page is a set of encoded instructions independent of a set of program instructions. FIG. 3b is a block diagram (120) of a set of program instructions in numerical form at a predefined offset in a page of memory. As shown, at a set location (122), the program instruction has numerical data (124), (126), (128), and (130). In the example shown herein the decode page is combined with the program instructions at a predefined position within the page. A page of memory is typically 4096 bytes in length. The offset shown herein is at position (122) in the page. Furthermore, in this example, the decode page is subtracted from the program instruction at the predefined offset position. FIG. 3c is a block diagram (140) of a set of decoded program instruction data at offset position (142) shown by combining the encoded instructions with the decode page. In this example, at a set location (142), the instructions have data (144), (146), (148), and (150). The instructions shown in FIGS. 3a-3c use a rudimentary mathematical operator. Preferably, the mathematical operator is in the form of a hardware binary operation that applies the underlying principle illustrated in FIGS. 3a-3c. Accordingly, the decoding of program instructions shown in FIGS. 3a-3c is an example of applying a decode page to a page of encoded program instructions.

### Advantages Over the Prior Art

The process of encoding a single page of memory and formatting this page as a decode page takes advantage of the fact that memory is divided into pages and that relocatable programs are always moved by whole pages. In addition, by setting the location of the decode page in one of the hardware registers the actual location of the decode page remains separate from the program instructions. The location of the decode page assigned to a hardware register may be changed to a different hardware register for each execution of the program instructions to further prevent an outside source from locating the decode page. Accordingly, the use of the hardware registers for storing the location of the decode pages may enable the location of the decode page to become portable and make locating the decode page more complex.

### ALTERNATIVE EMBODIMENTS

It will be appreciated that, although specific embodiments of the invention have been described herein for purposes of illustration, various modifications may be made without departing from the spirit and scope of the invention. In particular, it may become desirable to disable the decode page under certain circumstances. The hardware register that stores the location of the decode page may be set to zero or another value to deactivate the decode page and to enable the program instructions to execute without use of the decode page. Additionally, the operating system may be employed to change the location of the hardware register that stores the location of the decode page for execution of a new program. Accordingly, the scope of protection of this invention is limited only by the following claims and their equivalents.

We claim:

1. A method for encoding a program comprising:
creating a single page for decoding an encoded program instruction; and
decoding said program instruction with said single page prior to program execution.

2. The method of claim 1, wherein the step of decoding said program instruction includes combining instructions at each offset of the program with contents of the single page at a matching offset.

3. The method of claim 1, wherein the step of decoding said program instruction includes generating binary data to form a valid instruction stream.

4. The method of claim 1, further comprising setting an address of said single page in a hardware register prior to decoding said program instruction.

5. The method of claim 5, further comprising switching said hardware register in response to execution of a new program.

6. A computer system comprising:
an encoded program instruction;
a single decode page adapted to decode said encoded program instruction; and
a manager adapted to apply said single decode page to said encoded program instruction prior to program execution.

7. The system of claim 6, wherein said manager is adapted to combine said encoded program instruction at each offset of an associated program with contents of said single decode page at a matching offset.

8. The system of claim 6, wherein said manager is adapted to generate binary data to form a valid instruction stream.

9. The system of claim 6, further comprising a page manager adapted to locate an address of said page in a hardware register.

10. The system of claim 9, wherein said hardware register is adapted to be switched in response to execution of a new program.

11. An article comprising:
a computer-readable signal-bearing medium;
means in the medium for creating a single page for decoding an encoded program instruction; and
means in the medium for decoding said program instruction with said single page prior to program execution.

12. The article of claim 11, wherein said medium is selected from a group consisting of: a recordable data storage medium, and a modulated carrier signal.

13. The article of claim 11, wherein the means for decoding said program instruction includes combining instructions at each offset of the program with contents of the single page at a matching offset.

14. The article of claim 11, wherein the means for decoding said program instruction includes generating binary data to form a valid instruction stream.

15. The article of claim 11, further comprising means for setting an address of said page in a hardware register prior to decoding said program instruction.

16. The article of claim 15, further comprising means for switching said hardware register in response to execution of a new program.
